(19) United States
(12) Patent Application Publication
(10) Pub. No.: US 2022/0131054 A1
(43) Pub. Date: Apr. 28, 2022

(54) LIGHT-EMITTING PACKAGE AND METHOD OF MANUFACTURING THE SAME

(71) Applicant: Unimicron Technology Corp., Taoyuan (TW)

(72) Inventors: Kai-Ming YANG, Hsinchu County (TW); Chen-Hao LIN, Keelung City (TW); Tzu-Nien LEE, Hsinchu (TW)

(21) Appl. No.: 17/102,458

(22) Filed: Nov. 24, 2020

(30) Foreign Application Priority Data
Oct. 22, 2020 (TW) 109136750

(51) Int. Cl. H01L 33/54; H01L 33/62; H01L 33/00; H01L 33/56

(52) U.S. Cl. CPC H01L 33/54; H01L 33/62; H01L 2933/0066; H01L 33/56; H01L 2933/005; H01L 33/005

(57) ABSTRACT

A light-emitting package includes a black encapsulating member, a plurality of light-emitting components and a circuit structure. The black encapsulating member has a first surface and a second surface opposite to the first surface. The light-emitting components are embedded in the black encapsulating member. Each light-emitting component has a light-emitting surface, a back surface opposite to the light-emitting surface, and a plurality of pads disposed on the back surface. The light-emitting surface of each light-emitting component is exposed on the first surface and is flush with the first surface. The pads of each light-emitting component are exposed on the second surface. The circuit structure is disposed on the second surface and electrically connected to the pads.

### CROSS-REFERENCE TO RELATED APPLICATION

This application claims priority to Taiwan Application Serial Number 109136750, filed Oct. 22, 2020, which is herein incorporated by reference in its entirety.

### BACKGROUND

### Field of Invention

The present disclosure relates to a semiconductor package and the method of manufacturing thereof. More particularly, the present disclosure relates to a light-emitting package and the method of manufacturing the same.

### Description of Related Art

A conventional light-emitting diode (LED) display panel is usually assembled by two substrates stacked on each other, where one of the substrates is a light-emitting substrate mounted with a plurality of LEDs, whereas the other is a color filter substrate. The LEDs of the light-emitting substrate are usually white or blue LEDs, and the color filter substrate can use optical filter layers or phosphorescent layers for converting the light emitted from the LEDs into red light, green light, and blue light, so that the LED display panel can display images.

The color filter substrate usually has a black matrix, in which the black matrix can block the red light, the green light, and the blue light each with a large angle of emergence to reduce light leakage, thereby reducing the adverse influence on the image due to mixing the red light, the green light, and the blue light. Since the conventional LED display panel is usually assembled by the light-emitting substrate and the color filter substrate, the alignment between the light-emitting substrate and the color filter substrate has to be accurate during the assembly process. Otherwise, the black matrix maybe covers some of LEDs completely to cause a partial area of the display panel to appear a dark state, thereby reducing the quality of the image.

### SUMMARY

At least one embodiment of the disclosure provides a light-emitting package including a black encapsulating member and a plurality of light-emitting components embedded in the black encapsulating member.

At least one embodiment of the disclosure provides a method of manufacturing the abovementioned light-emitting package.

A light-emitting package according to at least one embodiment of the disclosure includes a black encapsulating member, a plurality of light-emitting components, and a circuit structure. The black encapsulating member has a first surface and a second surface opposite to the first surface. The light-emitting components are embedded in the black encapsulating member. Each of the light-emitting components has a light-emitting surface, a back surface opposite to the light-emitting surface, and a plurality of pads disposed on the back surface. The light-emitting surface of each light-emitting component is exposed on the first surface and flush with the first surface. The pads of each light-emitting component are exposed on the second surface. The circuit structure is disposed on the second surface and electrically connected to the pads.

A method of manufacturing a light-emitting package according to at least one embodiment of the disclosure includes the following steps. A plurality of light-emitting components are provided, where each of the light-emitting components has a light-emitting surface, a back surface opposite to the light-emitting surface, and a plurality of pads disposed on the back surface. The light-emitting components are disposed on the first holder, where there are a plurality of gaps in between all the light-emitting components, and the pads are located between the light-emitting surface and the first holder. A black encapsulating material is formed on the first holder, in which the black encapsulating material covers the light-emitting components and the light-emitting surfaces thereof, and fills the gaps. The black encapsulating material has a first surface and a second surface opposite to the first surface, in which both the light-emitting components and the second surface are located between the first surface and the first holder. Part of the black encapsulating material is removed from the first surface, so as to form a black encapsulating member and to expose the light-emitting surface. The first holder is separated from both the black encapsulating member and the light-emitting components, so as to expose the pads. A circuit structure is formed on the exposed pads, in which the circuit structure is electrically connected to the pads.

Based on the above, the black encapsulating member can be used as a black matrix and have the function of reducing light leakage, thereby reducing the adverse influence on the image caused by light leakage. Moreover, since the light-emitting components are embedded in the black encapsulating member, the light-emitting components and the black encapsulating member can be integrated into one without both assembly and alignment of two substrates, e.g., the light-emitting substrate and the color filter substrate.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1 to 7 are schematic cross-sectional views of a method of manufacturing a light-emitting package according to at least one embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Secondly, the words “about”, “approximately”, or “substantially” appearing in the content of the present disclosure not only cover the clearly stated values and range of values, but also include those with ordinary knowledge in the technical field to which the invention belongs. The allowable deviation range, which can be determined by the error generated during the measurement, and the error is caused by the limitation of the measurement system or the process conditions, for example. In addition, “about” may be expressed within one or more standard deviations of the above values, such as within ±30%, ±20%, ±10%, or ±5%. The words “about”, “approximately” or “substantially” appearing in this text can choose acceptable deviation range or standard deviation according to optical properties, etching properties, mechanical properties or other properties, not just one Standard deviation to apply all the above optical properties, etching properties, mechanical properties and other properties.

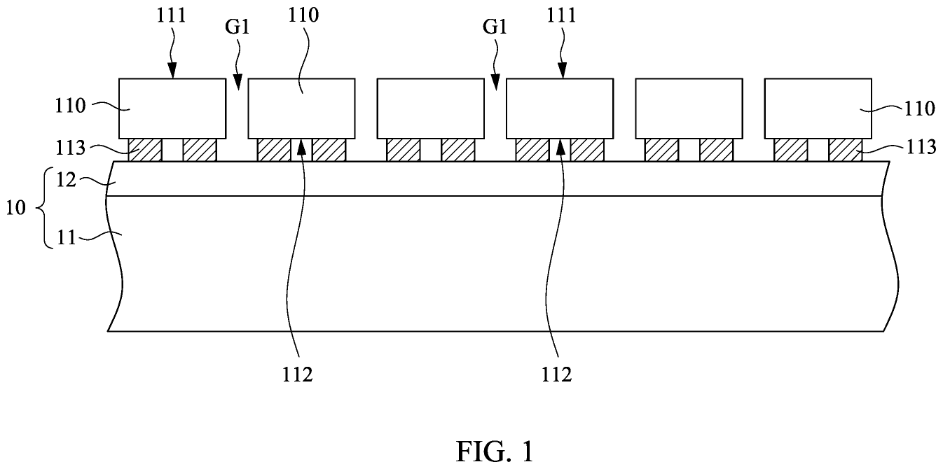

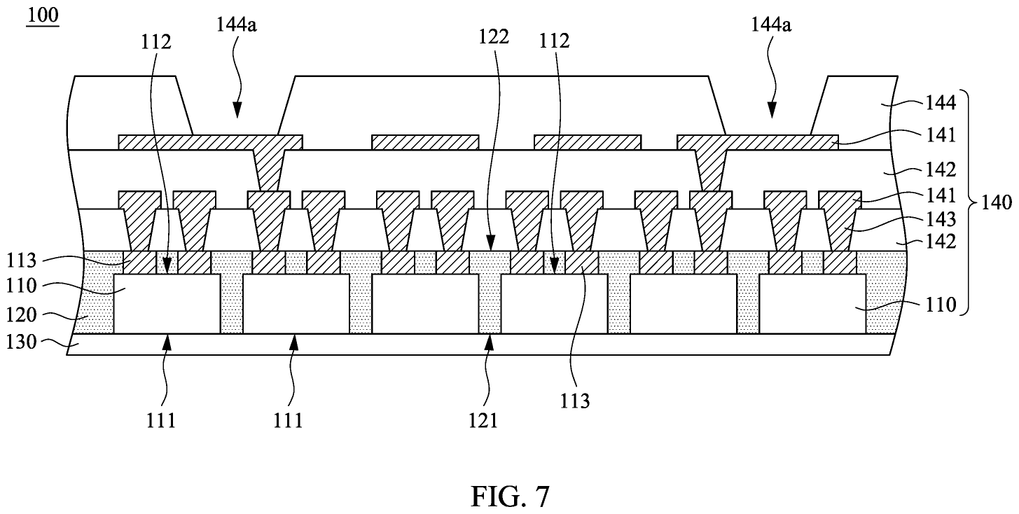

FIGS. 1 to 7 are schematic cross-sectional views of a method of manufacturing a light-emitting package according to at least one embodiment of the disclosure, in which FIG. 7 illustrates a light-emitting package 100 which is complete. Referring to FIG. 1, in the manufacturing method of the embodiment, first, a plurality of light-emitting components 110 are provided, in which the light-emitting components 110 may be solid-state light-emitting components, such as light-emitting diodes (LEDs). Moreover, the light-emitting components 110 may be LED dies, which are unpackaged LEDs.

Each of the light-emitting components 110 has a light-emitting surface 111, a back surface 112 opposite to the light-emitting surface 111, and a plurality of pads disposed on the back surface 112. A light-emitting component 110 may have two pads 113, and the two pads 113 are an anode and a cathode. When the light-emitting component 110 receives electricity from the pads 113, the light-emitting component 110 can emit light from the light-emitting surface 111. In the present embodiment, the light-emitting components 110 may include a plurality of red LEDs, a plurality of green LEDs, and a plurality of blue LEDs, so the light-emitting components 110 can emit red light, green light, and blue light.

Next, the light-emitting components 110 are disposed on the first holder 10. The first holder 10 can hold and fix the light-emitting components 110, and can fix the light-emitting components 110 by electrostatic suck, vacuum suck, or adhesive. In the embodiment shown in FIG. 1, the first holder 10 may include a supporting substrate 11 and an adhesive layer 12, where the adhesive layer 12 is formed on the supporting substrate 11.

The supporting substrate 11 may be a rigid board, such as metal plate, glass plate, or ceramic plate. The adhesive layer 12 can adhere to the light-emitting components 110 temporarily, so that the light-emitting components 110 are attached to the first holder 10 temporarily. The adhesive layer 12 may be a polymer material layer and can be made of polymer material, such as polydimethylsiloxane (PDMS).

After the light-emitting components 110 are disposed on the first holder 10, the pads 113 are located between the light-emitting surface 111 and the first holder 10. Taking FIG. 1 for example, the adhesive layer 12 can touch and adhere to the pads 113 of the light-emitting components 110, but not touch the light-emitting surface 111, so that the back surface 112 is closer to the light-emitting surface 111 than the first holder 10. Accordingly, the pads 113 are located between the light-emitting surface 111 and the first holder 10. The light-emitting components 110 disposed on the first holder 10 are separated from each other. Thus, there are a plurality of gaps G1 in between all the light-emitting components 110, where the light-emitting components 110 can be arranged in an array or a matrix on the first holder 10.

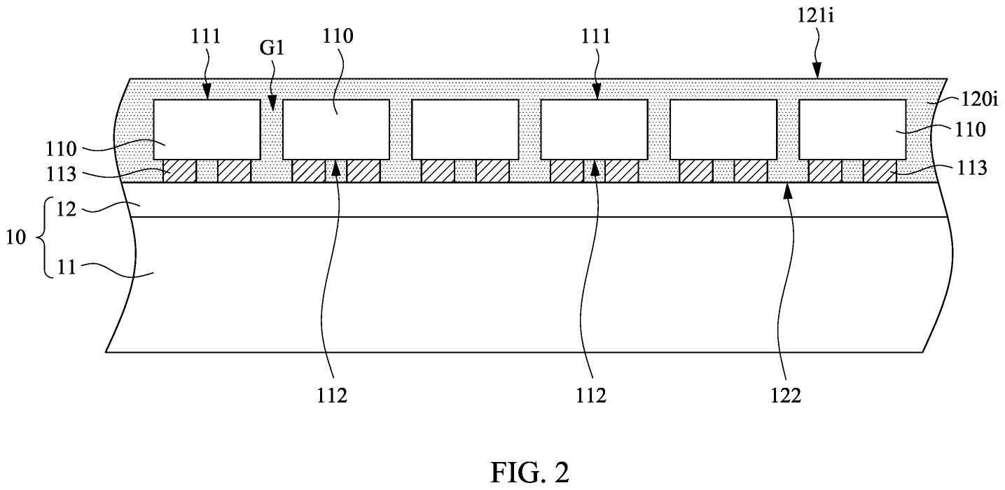

Referring to FIG. 2, next, a black encapsulating material 120i is formed on the first holder 10. The optical density (OD) of the black encapsulating material 120i is larger than 2, where the OD herein corresponds to absorbance. Hence, the black encapsulating material 120i has a very low transmittance, so that the black encapsulating material 120i can block visible light effectively. In addition, the black encapsulating material 120i can be formed by printing, spraying, or Injection molding, where the black encapsulating material 120i can has rigidity or flexibility.

The black encapsulating material 120i covers the light-emitting components 110 and the light-emitting surface 111 thereof, and fills the gap G1, where the black encapsulating material 120i can directly touch the light-emitting components 110, as shown in FIG. 2. Hence, the light-emitting components 110 are embedded in the black encapsulating material 120i. In addition, in the embodiment as shown in FIG. 2, the space (not marked), such as a gap, between the back surfaces 112 of the light-emitting components 110 and the first holder 10 can be filled with the black encapsulating material 120i, so the black encapsulating material 120i also can touch the pads 113 directly.

The black encapsulating material 120i has a first surface 121i and a second surface 122 opposite to the first surface 121i, in which both the light-emitting components 110 and the second surface 122 are located between the first surface 121i and the first holder 10. Taking FIG. 2 for example, the first surface 121i and the second surface 122 are the upper surface and the lower surface of the black encapsulating material 120i respectively, in which the second surface 122 can directly touch the adhesive layer 12 of the first holder 10.

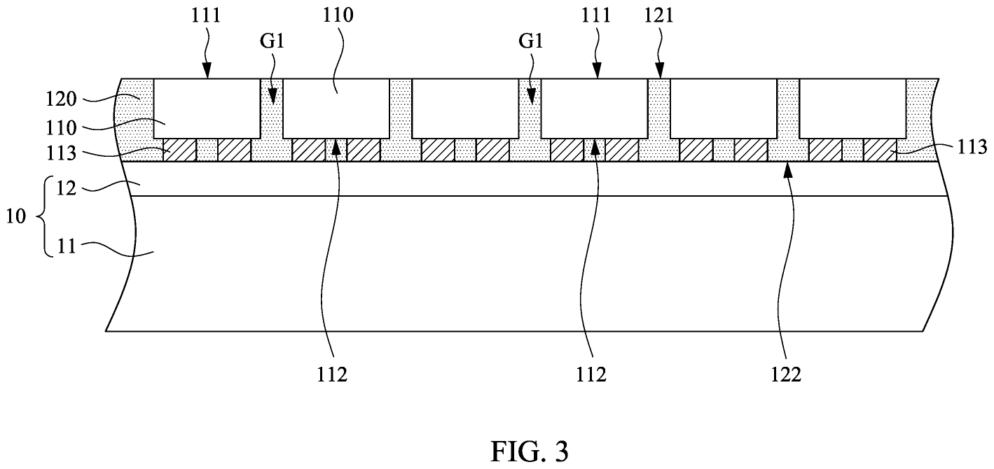

Referring to FIGS. 2 and 3, next, part of the black encapsulating material 120i is removed from the first surface 121i, so as to form the black encapsulating member 120 and to expose the light-emitting surfaces 111, in which the light-emitting components 110 are embedded in the black encapsulating member 120, and the black encapsulating member 120 can directly touch the light-emitting components 110. The light-emitting components 110 can be arranged in an array or a matrix on the first holder 10, and the black encapsulating material 120i fills the gap G1, so that the black encapsulating member 120 can be in the shape of a mesh. In addition, since the black encapsulating material 120i can have rigidity or flexibility, so the black encapsulating member 120 also can have rigidity or flexibility.

The black encapsulating member 120 has a first surface 121 and a second surface 122 opposite to the first surface 121. In the process of forming the black encapsulating member 120, the part of the black encapsulating material 120i is removed from the first surface 121i, not from the second surface 122. Hence, the black encapsulating member 120 and the black encapsulating material 120i all have the same second surface 122, but the first surface 121 belonging to the black encapsulating member 120 is not the original first surface 121i. Moreover, the light-emitting surface 111 of each of the light-emitting components 110 is exposed on the first surface 121 and flush with the first surface 121.

There are a lot of ways to remove the part of the black encapsulating material 120i, for example, etching. In the present embodiment, the black encapsulating material 120i can be polished from the first surface 121i, so as to decrease the thickness of the black encapsulating material 120i and to cause that the thickness of the black encapsulating member 120 is substantial equal to the that of the light-emitting component 110. In addition, since the OD (optical density) of the black encapsulating material 120i is larger than 2, so that the OD of the black encapsulating member 120 is also larger than 2. That is, the black encapsulating member 120 also can block visible light effectively.

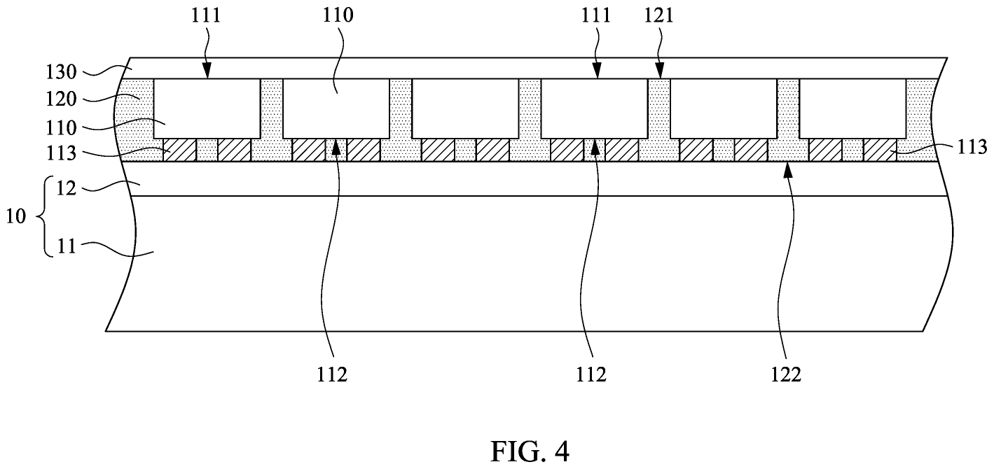

Referring to FIG. 4, after removing the part of the black encapsulating material 120i from the first surface 121i, that is, after forming the black encapsulating member 120, a transparent protective layer 130 can be formed on both the black encapsulating member 120 and the light-emitting surfaces 111, where the transparent protective layer 130 disposed on the first surface 121 of the black encapsulating member 120 covers the light-emitting surfaces 111 of the light-emitting components 110. The transparent protective layer 130 can be formed by printing or spraying, and the material of the transparent protective layer 130 can be silicone base material, epoxy base material, or polyimide (PI) base material, or any combination of these materials.

The transparent protective layer 130 has good transmittance. For example, the transparent protective layer 130 has the transmittance lager than 95% over the wavelength ranging between 300 nm and 800 nm, so that the light coming from the light-emitting components 110 can basically penetrate the transparent protective layer 130. However, the transmittance of the transparent protective layer 130 is not limited to the abovementioned range. In addition, the manufacturing method of the present embodiment may include the step of forming the transparent protective layer 130, but in other embodiment, the transparent protective layer 130 may not be formed. In other words, the transparent protective layer 130 shown in FIG. 4 can be omitted, and the manufacturing method of the present embodiment is not limited to including the step of forming the transparent protective layer 130.

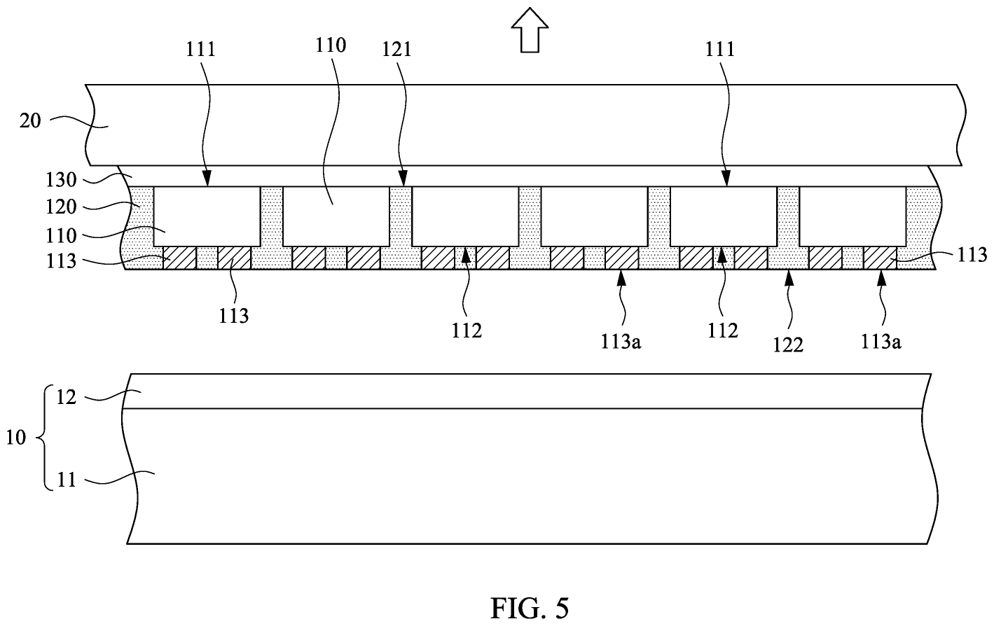

Referring to FIG. 5, afterwards, the first holder 10 is separated from both the black encapsulating member 120 and the light-emitting components 110. That is, both the black encapsulating member 120 and the light-emitting components 110 depart from the first holder 10, so as to expose the pads 113, where the pads 113 of each of the light-emitting components 110 are exposed on the second surface 122 of the black encapsulating member 120. Each of the pads 113 has an outer surface 113a, and the outer surfaces 113a of the pads 113 are exposed on the second surface 122 and flush with the second surface 122.

In the process of separating the first holder 10 from both the black encapsulating member 120 and the light-emitting components 110, both the black encapsulating member 120 and the light-emitting components 110 can be disposed on and connected to the second holder 20. The second holder 20 can be the same as the first holder 10. That is, the second holder 20 can have stickiness to adhere to both the black encapsulating member 120 and the light-emitting components 110 temporarily. Alternatively, the second holder 20 which may be an electrostatic chuck (E Chuck) or a vacuum chuck is connected to and attached to the light-emitting components 110 via electrostatic adsorption or vacuum sucking.

After the black encapsulating member 120 and the light-emitting components 110 are disposed on and connected to the second holder 20, the light-emitting surface 111 is located between the second holder 20 and the back surface 112 while the second holder 20 covers the light-emitting surfaces 111. Afterwards, the second holder 20 can move away from the first holder 10, so that the first holder 10 can be separated from both the black encapsulating member 120 and the light-emitting components 110 to expose the pads 113.

In the present embodiment, the first holder 10 is separated from both the black encapsulating member 120 and the light-emitting components 110 by using the second holder 20. However, in other embodiment, the first holder 10 can be separated from both the black encapsulating member 120 and the light-emitting components 110 by peeling directly without using the second holder 20. Hence, the second holder 20 shown in FIG. 5 is illustrated for example and not limited to separating the first holder 10 from both the black encapsulating member 120 and the light-emitting components 110.

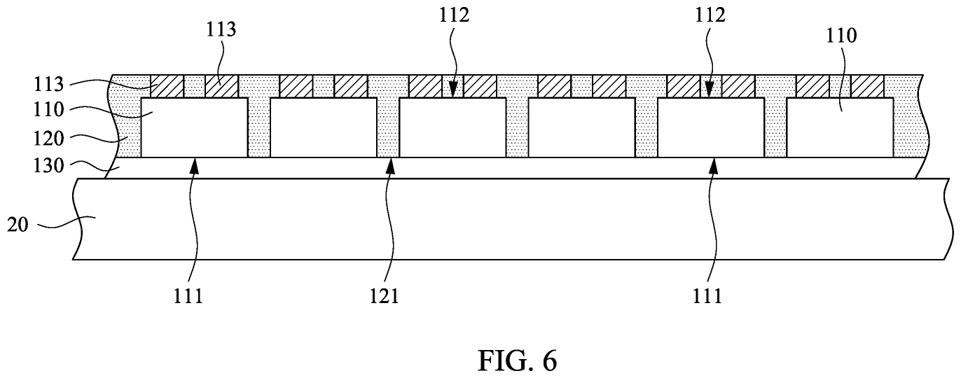

Referring to FIGS. 6 and 7, next, in the situation that the second holder 20 is attached to both the black encapsulating member 120 and the light-emitting components 110, the second holder 20 can be turned over, so as to let the exposed pads 113 face up, as shown in FIG. 6. Afterwards, a circuit structure 140 is formed on the exposed pads 113, as shown in FIG. 7. In other words, the circuit structure 140 is formed on the pads 113 after the transparent protective layer 130 is formed, so the circuit structure 140 is disposed on the second surface 122 of the black encapsulating member 120. The circuit structure 140 is electrically connected to the pads 113, so that the light-emitting components 110 can receive electricity via the circuit structure 140 for generating light.

After forming the circuit structure 140, a second holder 20 is separated from both the black encapsulating member 120 and the light-emitting components 110, and a light-emitting package 100 including the light-emitting components 110, the black encapsulating member 120, the transparent protective layer 130, and the circuit structure 140 is basically complete. The method of forming the circuit structure 140 can employ the existing manufacture of printed circuit board (PCB) or electronic packaging carrier, such as building-up or stacking-up. In the embodiment of FIG. 7, the circuit structure 140 includes a plurality of wiring layers 141, a plurality of insulation layers 142 and 144, and a plurality of conductive connection members 143. The insulation layers 142 and 144 are stacked on each other, and the insulation layer 144 is located on the outermost side of the circuit structure 140.

The insulation layer 144 can be a solder mask and have a plurality of openings 144a, in which the openings 144a can partially expose the adjacent wiring layer 141, for example, expose the pads (not marked) of the wiring layer 141. The wiring layer 141 exposed by the openings 144a can be electrically connected to a circuit board (not shown) via solder or wire-bonding, so that the light-emitting package 100 can be mounted on and electrically connected to the circuit board, in which the circuit board may be a PCB, an electronic packaging carrier, a flexible wiring board, or a rigid-flex wiring board. In addition, in the embodiment of FIG. 7, the openings 144a are solder mask defined (SMD), but in other embodiment, the openings 144a may be non-solder mask defined (NSMD).

The material of the insulation layer 142 can include ceramic material or polymer material, in which the polymer material may be epoxy. The insulation layer 142 can further be made of prepreg, so the material of the insulation layer 142 can include fiberglass. In addition, since the black encapsulating member 120 can have flexibility, the material of the insulation layer 142 can be selected from a flexible polymer material, such as PI or polyethylene terephthalate (PET), so that the light-emitting package 100 has flexibility, thereby facilitating the production of flexible display panel.

Each of the wiring layers 141 is formed between adjacent two of the insulation layers 142 and 144. Taking FIG. 7 for example, one of the wiring layers 141 is formed between two adjacent insulation layers 142, whereas another wiring layer 141 is formed between two adjacent insulation layers 142 and 144. The conductive connection members 143 are located in the insulation layer 142 and connected to the wiring layers 141, so that the wiring layers 141 can be electrically connected to each other via the conductive connection members 143, where the conductive connection members 143 can be conductive blind via structures, conductive through hole structures, or conductive embedded hole structures and formed by electroplating.

It is worth mentioning that in the embodiment as shown in FIG. 7, the circuit structure 140 includes two wiring layers 141, but the circuit structure 140 can include only one, three, or more than three wiring layers 141 in other embodiment. Thus, the wiring layers 141 shown in FIG. 7 is illustrated for example and not limited to the quantity of the wiring layer 141 included by the circuit structure 140. Moreover, since the transparent protective layer 130 in FIG. 4 can be omitted, the light-emitting package 100 can not include the transparent protective layer 130. In other words, the transparent protective layer 130 shown in FIG. 7 can be omitted.

Consequently, the black encapsulating member can be used as a black matrix and block the light coming from the light-emitting component with a large angle of emergence. Hence, the black encapsulating member can have the function of reducing light leakage to reduce the adverse influence on the image caused by light leakage. Moreover, since the light-emitting components are embedded in the black encapsulating member, the light-emitting components and the black encapsulating member can be integrated into one without both assembly and alignment of the two substrates.

Compared to the conventional LED display panel which is assembled by the light-emitting substrate and the color filter substrate, the light-emitting package according to at least one embodiment not only has advantages of simplifying the manufacture and shortening the time of the manufacture, but also can effectively solve the disadvantage of the black matrix completely covering some light-emitting diodes due to inaccurate alignment in the prior art. Therefore, the light-emitting package can help to improve the image quality in the display panel application.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A light-emitting package, comprising:
a black encapsulating member, having a first surface and a second surface opposite to the first surface;
a plurality of light-emitting components, embedded in the black encapsulating member, wherein each of the light-emitting components has a light-emitting surface, a back surface opposite to the light-emitting surface, and a plurality of pads disposed on the back surface, the light-emitting surface of each of the light-emitting components exposed on the first surface and flush with the first surface, the pad of each of the light-emitting components exposed on the second surface; and
a circuit structure, disposed on the second surface and electrically connected to the pads.

2. The light-emitting package of claim 1, wherein an optical density of the black encapsulating member is larger than 2.

3. The light-emitting package of claim 1, wherein the light-emitting components are all a plurality of light-emitting diode (LED) dies.

4. The light-emitting package of claim 1, wherein each of the pads has an outer surface, and the outer surfaces of the pads are exposed on the second surface and flush with second surface.

5. The light-emitting package of claim 1, wherein the black encapsulating member directly touches the light-emitting components.

6. The light-emitting package of claim 1, wherein the light-emitting components comprise a plurality of red LEDs, a plurality of green LEDs, and a plurality of blue LEDs.

7. The light-emitting package of claim 1, further comprising a transparent protective layer disposed on the first surface and covering the light-emitting surface of the light-emitting components.

8. The light-emitting package of claim 1, wherein the light-emitting components are separated from each other, so that there are a plurality of gaps in between all the light-emitting components, wherein the black encapsulating member fills the gap.

9. A method of manufacturing a light-emitting package, comprising:
providing a plurality of light-emitting components, wherein each of the light-emitting components has a light-emitting surface, a back surface opposite to the light-emitting surface, and a plurality of pads disposed on the back surface;
disposing the light-emitting components on a first holder, wherein there are a plurality of gaps in between all the light-emitting components, and the pads are located between the light-emitting surface and the first holder;
forming a black encapsulating material on the first holder, wherein the black encapsulating material covers the light-emitting components and the light-emitting surfaces thereof, and fills the gap, wherein the black encapsulating material has a first surface and a second surface opposite to the first surface, and both the light-emitting components and the second surface are located between the first surface and the first holder;
removing a part of the black encapsulating material from the first surface, so as to form a black encapsulating member and to expose the light-emitting surfaces;
separating the first holder from both the black encapsulating member and the light-emitting components, so as to expose the pads; and
forming a circuit structure on the pads which are exposed, wherein the circuit structure is electrically connected to the pads.

10. The method of manufacturing a light-emitting package according to claim 9, wherein removing the part of the black encapsulating material from the first surface comprises polishing the black encapsulating material from the first surface.

11. The method of manufacturing a light-emitting package according to claim 9, after removing the part of the black encapsulating material from the first surface, further comprising:
forming a transparent protective layer on both the black encapsulating member and the light-emitting surfaces.

12. The method of manufacturing a light-emitting package according to claim 11, wherein the circuit structure is formed after the transparent protective layer is formed.

13. The method of manufacturing a light-emitting package according to claim 9, wherein in a process of separating the first holder from both the black encapsulating member and the light-emitting components, the black encapsulating member and the light-emitting components are both disposed on and connected to a second holder which covers the light-emitting surfaces.
